(19) United States
(12) Patent Application Publication
(10) Pub. No.: US 2015/0035541 A1
(43) Pub. Date: Feb. 5, 2015

(54) SIGNAL INTEGRITY TEST APPARATUS AND METHOD FOR TESTING SIGNAL INTEGRITY OF ELECTRONIC PRODUCT

(71) Applicant: FIH (Hong Kong) Limited, Kowloon (HK)

(72) Inventor: MING-SHIU OU YANG, New Taipei (TW)

(21) Appl. No.: 14/341,095

(22) Filed: Jul. 25, 2014

(30) Foreign Application Priority Data
Jul. 30, 2013 (TW) 102127275

(51) Int. Cl. G01R 31/02; G06K 7/14; G06K 7/10

(52) U.S. Cl. CPC G01R 31/02; G06K 7/10861; G06K 7/1413; G06K 7/1417; Y10S 901/44
USPC 324/511; 901/44

(57) ABSTRACT

In a method for testing signal integrity of an electronic product using a signal integrity test apparatus, each electronic component of the electronic product includes a test label that identifies the electronic component. The signal integrity test apparatus includes a host computer, a robot device, an oscilloscope, a camera device, and a probe. The host computer is installed with a signal integrity test system that controls the signal integrity test apparatus to test signal integrity of the electronic product. The robot device includes a first robot arm and a second robot arm. The first robot arm controls the camera device to capture an image of the test label coupled to each electronic component. The second robot arm controls the probe to touch each electronic component. The oscilloscope measures voltage signals outputted from the electronic components to generate a signal integrity report of the electronic product.

### CROSS-REFERENCE TO RELTATED APPLICATIONS

This application claims priority to Taiwanese Patent Application No. 102127275 filed on Jul. 30, 2013 in the Taiwan Intellectual Property Office, the contents of which are incorporated by reference herein.

### FIELD

The present disclosure relates to a signal test system and method, and particularly to a signal integrity test apparatus and a method for automatically testing signal integrity of electronic components of an electronic product.

### BACKGROUND

Currently, electronic components, such as resistors, capacitors, inductors, and integrated circuit (IC) chips, are tested prior to assembly onto an electronic product, such as a printed circuit board (PCB). The signal integrity of the electronic components on the PCB can be tested manually.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a diagrammatic view of an example embodiment of a signal integrity test apparatus.

FIG. 2 shows a plan view of an example of a test label with a bar code.

FIG. 3 shows a plan view of another example of a test label with a quick response code.

FIG. 4 is a block diagram illustrating an example embodiment of the host computer.

FIG. 5 is a flowchart of an example embodiment of a method for automatically testing signal integrity of an electronic product.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented. The term “module” refers to logic embodied in computing or firmware, or to a collection of software instructions, written in a programming language, such as, Java, C, or assembly. One or more software instructions in the modules may be embedded in firmware, such as in an erasable programmable read only memory (EPROM). The modules described herein may be implemented as either software and/or computing modules and may be stored in any type of non-transitory computer-readable medium or other storage device. Some non-limiting examples of non-transitory computer-readable media include CDs, DVDs, BLU-RAY, flash memory, and hard disk drives. The term “comprising” means “including, but not necessarily limited to”; it specifically indicates open-ended inclusion or membership in a so-described combination, group, series and the like. The term “coupled” is defined as connected, whether directly or indirectly through intervening components, and is not necessarily limited to physical connections. The connection can be such that the objects are permanently connected or releasably connected. The term “electronically coupled” can include any coupling that is via a wired or wireless connection. The electronic coupling can be through one or more components or it can include a direct connection between the described components.

The present disclosure presents an apparatus and method to measure the signal integrity of an electronic component installed on an electronic product. An electronic component as described herein is any device having one or more electronic components coupled thereto. The present disclosure measures the signal integrity of one or more of the electronic components installed on the electronic product. As the electronic component is already installed on the electronic product, the resistance of an electronic component due to the skin effect and electromagnetic coupling caused by radiation can be accounted for during the testing procedure. Thus, the undesired effects can accounted for and signal integrity test result for the electronic product can be improved.

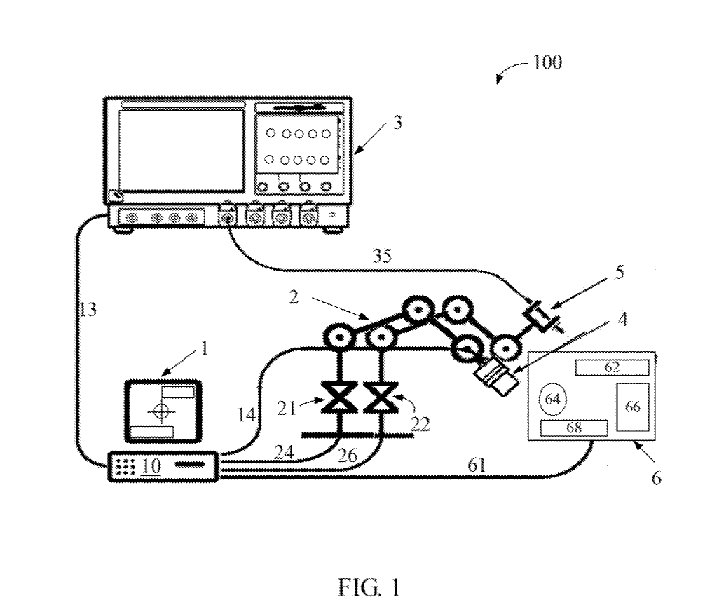

FIG. 1 illustrates a diagrammatic view of an example embodiment of a signal integrity test apparatus 100. In the embodiment, the signal integrity test apparatus 100 includes, but is not limited to, a host computer 1, a robot device 2, an oscilloscope 3, a camera device 4, and a probe 5. The host computer 1 is electronically coupled to the robot device 2, and connects to the oscilloscope 3. As illustrated, the host computer 1 is electronically coupled to the robot device 2 by a wire 24, 26. In at least one embodiment, the wire 24, 26 can allow for electronic data communication and power to be provided from the host computer 1 to the robot device 2. As illustrated, two wires 24, 26 are implemented such that the first wire 24 is coupled to the first robot arm 21 and the second wire 26 is coupled to the second robot arm 22. In other embodiments, a single wire can be coupled to one of the robot arms and a bridging wire can couple the first robot arm 21 to the second robot arm 22.

FIG. 1 illustrates only one example of the signal integrity test apparatus 100, and other examples can comprise more or fewer components than those shown in the embodiment, or have a different configuration of the various components. For example, while the data connections between the components is illustrated as a wired connection, the data connections can be wireless data connections. The wireless data connections can include both local and longer range wireless connections. Examples of local wireless connections include BLUETOOTH connections. Examples of long range wireless data connections include WI-FI and cellular networks.

In the embodiment, the host computer 1 is electronically coupled to the oscilloscope 3 by a wire 13. In one example, the wire 13 can be configured to provide for signal communication between the host computer 1 and the oscilloscope 3. As illustrated, the camera device 4 is a camera body having a data line 14 connected to the host computer 1. In other embodiments, the oscilloscope 3 can be eliminated and the function of the oscilloscope 3 can be provided by a data conversion card located within the host computer 1. The host computer 1 can include a signal integrity test system 10 that controls the other components of the signal integrity test apparatus 100 to automatically test signal integrity of electronic components 62, 64, 66, 68 of the electronic product 6. As illustrated, the electronic product 6 can be coupled to the host computer 1 by a wired connection 61. In other examples, the electronic product 6 can be coupled to the host computer 1 by a wireless connection. In one embodiment, the electronic product 6 can be a printed circuit board (“PCB”) that is equipped with a plurality of electronic components, such as resistors, capacitors, inductors, and integrated circuit (“IC”) chips. As illustrated, the electronic product 6 includes four electronic components 62, 64, 66, 68. In one example, a first electronic component 62 can be a memory device. Additionally, a second electronic component 64 can be a processor. A third electronic component 66 can be an interface slot. A fourth electronic component 68 can be capacitor.

The robot device 2 includes a first robot arm 21 and a second robot arm 22. The first robot arm 21 can have the camera device 4 coupled thereto. The first robot arm 21 can be configured to move the camera device 4 based on instructions received from the host computer 1 to capture an image of a test label coupled to each of the electronic components 62, 64, 66, 68. The first robot arm 21 can move the camera device 4 in sequence from the first electronic component 62 to the fourth electronic component 68. While only four electronic components are illustrated, the first robot arm 21 can move the camera device 4 from a first electronic component to the last electronic component such that the camera records information of all electronic components. In other embodiments, the first robot arm 21 can move the camera device 4 across the electronic product 6 until a first electronic component is detected. The procedure can be repeated until all of the electronic components having associated labels are identified by the camera device 4.

The second robot arm 22 controls the probe 5 to touch test points of each electronic component. The test points may include an integrated circuit power supply pin (“VCC”) point of each electronic component, and a grounding (“GND”) point of each electronic component. The VCC point outputs a positive voltage signal of the electronic component, and the GND point outputs a negative voltage signal of the electronic component. The second robot arm 22 can be controlled to move the probe 5 after the camera device 4 and host computer 1 has detected an electronic component. In other embodiments, the second robot arm 22 can remain stationary until after the camera device 4 and the host computer 1 have identified all of the electronic components. In other embodiments, the second robot arm 22 can be controlled to begin testing after a predetermined number of electronic components have been identified.

The oscilloscope 3 measures integrity of the positive voltage signal and the negative voltage signal of the electronic component from the probe 5 through a signal line 35. The camera device 4 captures an image of the test label coupled to the electronic component, and sends the image of the test label to the host computer 1. The probe 5 detects the positive voltage signal outputted from the VCC point when the probe 5 touches the VCC point, and detects the negative voltage signal outputted from the GND point when the probe 5 touches the GND point.

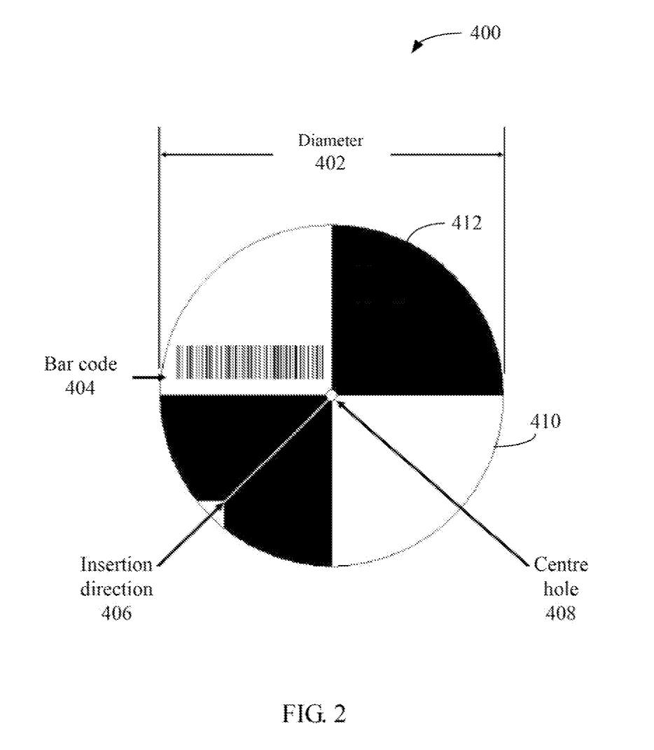

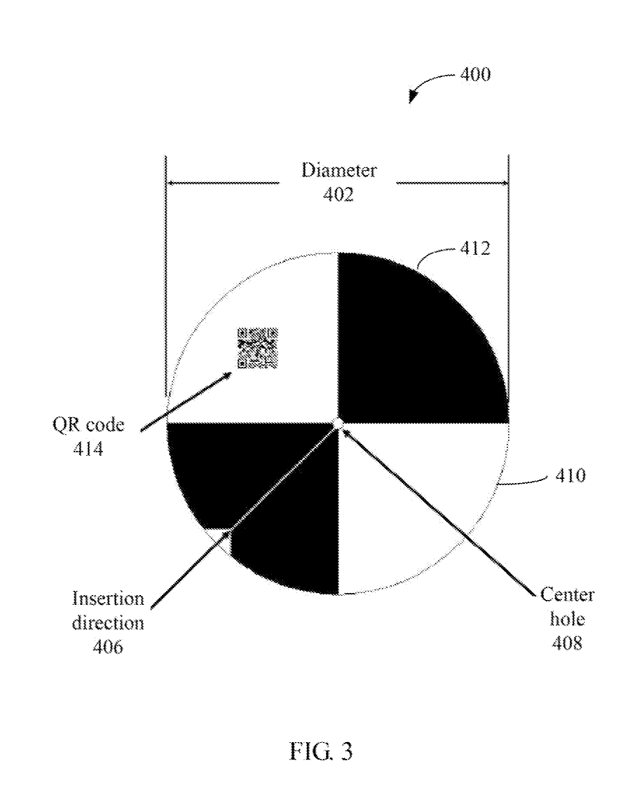

In the embodiment, each of the electronic components includes a test label that identifies a location of the electronic component and a name of a signal output from the electronic component. Examples of test labels 400 are illustrated in FIGS. 2 and 3. Each test label 400 includes a center hole 408, a signal identification code 404, 414, and an insertion direction 406 of the probe 5 when the probe 5 enters into the center hole 408 of the test label 400 to test the electronic component. As such, the probe 5 can touch the electronic component through the center hole 408 of the test label 400. The signal identification code 404, 414 can store a plurality of parameters, which includes a name of the output signal of the electronic component, and a touch stress parameter when the probe 5 touches the electronic component. In the embodiment, the signal identification code 404, 414 can be a bar code 404 or a quick response (QR) code 414.

FIG. 2 shows a plan view of an example of the test label 400 with the bar code 404. FIG. 3 shows a plan view of another example of the test label 400 with the QR code 414. As illustrated in FIGS. 2 and 3, the test label 400 is a circular label that has a diameter 402. In other embodiments, the shape of the test label 400 can be different. In some embodiments, the shape of the labels are uniform. In other embodiments, the shape of the test label 400 can be different in dependence upon what electronic component the label is going to be coupled to. Additionally, as illustrated, the label 400 includes one or more light regions 410 and one or more dark regions 412. The light region 410 and dark region 412 allow the camera device 4 to more easily detect the label 400. As illustrated, the test label 400 includes two light regions 410 and two dark regions 412. Other arrangements of color regions of the test label 400 can be implemented as well.

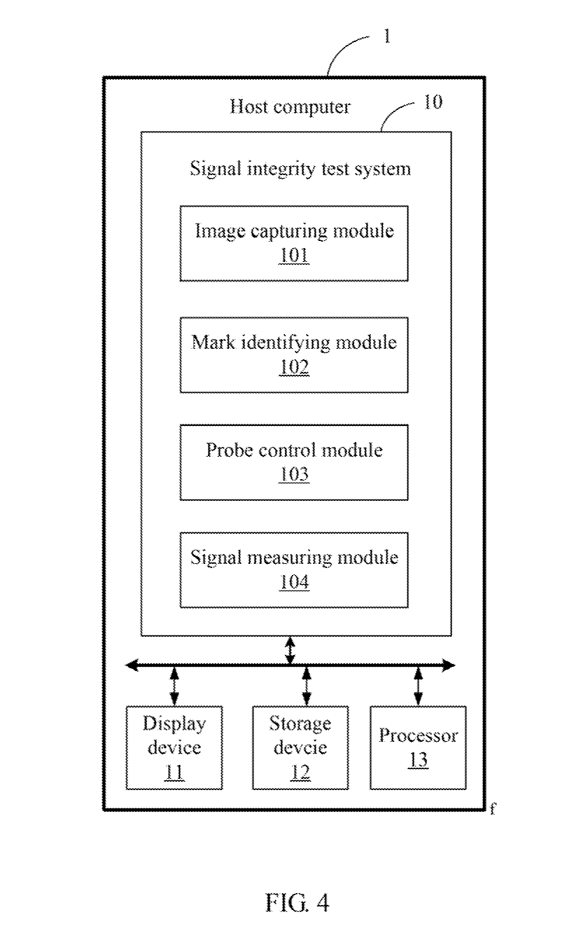

FIG. 4 is a block diagram illustrating an example embodiment of the host computer 1. In the example embodiment, the host computer 1 includes, but is not limited to, a signal integrity test system 10, a display device 11, a storage device 12, and at least one processor 13. In one embodiment, the storage device 12 can be an internal storage system, such as a flash memory, a random access memory (RAM) for temporary storage of information, and/or a read-only memory (ROM) for permanent storage of information. The storage device 12 can also be an external storage system, such as an hard disk, a storage card, or a data storage medium. In at least one embodiment, the storage device 12 can include two or more storage devices such that one storage device is a memory and the other storage device is a hard drive. Additionally, one or more of the storage devices can be located external relative to the host computer 1. The at least one processor 13 can be a central processing unit (CPU), a microprocessor, or other data processor chip that performs functions of the host computer 1.

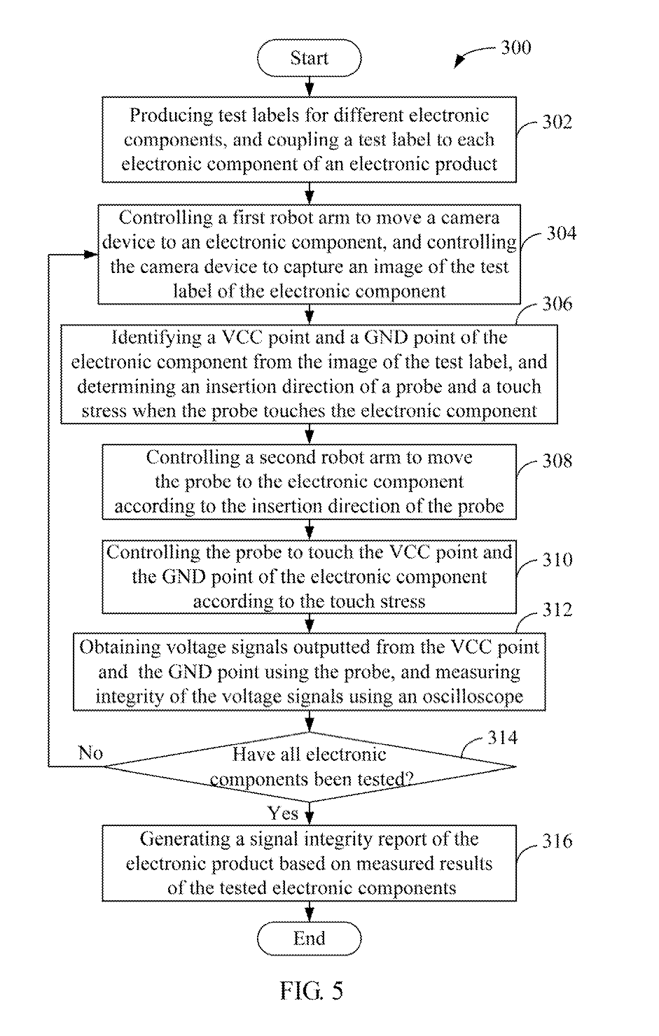

The signal integrity test system 10 comprises, but is not limited to, an image capturing module 101, a label identifying module 102, a probe control module 103, and a signal measuring module 104. Modules 101-104 can comprise computerized instructions in the form of one or more computer-readable programs that can be stored in a non-transitory computer-readable medium, for example the storage device 12, and executed by the at least one processor 13 of the host computer 1. The modules can be include the computerized instructions to execute the method as described below in relation to FIG. 5.

FIG. 5 illustrates a flowchart of an example embodiment of a method for automatically testing signal integrity of an electronic product. In an example embodiment, the method is performed by execution of computer-readable software program codes or instructions by at least one processor of a computing device, and can automatically test signal integrity of electronic components of the electronic product.

Referring to FIG. 5, a flowchart is presented in accordance with an example embodiment. The example method 300 is provided by way of example, as there are a variety of ways to carry out the method. The method 300 described below can be carried out using the configurations illustrated in FIGS. 1 and 4, for example, and various elements of these figures are referenced in explaining example method 300. Each block shown in FIG. 5 represents one or more processes, methods, or subroutines, carried out in the example method 300. Furthermore, the illustrated order of blocks is illustrative only and the order of the blocks can be changed. Additional blocks can be added or fewer blocks may be utilized without departing from this disclosure. The example method 300 can begin at block 302.

In block 302, the method 300 comprises producing a plurality of test labels for different electronic components. In block 302, the method 300 further comprise coupling a test label to each electronic component of the electronic product. As described above, the test label includes a center hole, a signal identification code, and an insertion direction of the probe when the probe plugs into the center hole of the test label. In at least one alternative embodiment, the producing of the test labels and coupling of the test label can be performed prior to the start of the method of the present disclosure. For example, a third party producer of the electronic components can produce the plurality of test labels and couple the test labels to the electronic components.

In block 304, the method 300 controls the first robot arm to move the camera device to an electronic component to be tested. The method 300 can include sending commands to drive the first robot arm to move the camera device into a position over an electronic component that is to be tested. In one embodiment, the location of the electronic device can be pre-programed so the motion of the first robot arm positions the camera device in a position that is close to the location in which the electronic component should be located. The method 300 can further include adjusting the first robot arm until the label of the electronic component is in the right field of view of the camera device. In block 304, the method 300 further controls the camera device to capture an image of the test label of the electronic component. The capturing of the image can include an instanteous image acquisition such that the image data is not stored permanently. In other examples, the image data can be stored permanently. Still further, the method 300 can include using video images taken from the camera device rather than still images.

In block 306, the method 300 identifies a VCC point and a GND point of the electronic component from the image of the test label. In the embodiment, the VCC point outputs a positive voltage signal of the electronic component, and the GND point outputs a negative voltage signal of the electronic component. In block 306, the method 300 further determines an insertion direction of the probe and a touch stress when the probe touches the electronic component.

In block 308, the method 300 controls the second robot arm to move the probe to the electronic component according to the insertion direction of the probe. The test labels 400 illustrated in FIG. 2 and FIG. 3 show the insertion direction, as described above, of the probe when the electronic component is touched by the probe. The method 300 further generates a second drive command to drive the second robot arm to move the probe to aim at the electronic component.

In block 310, the method 300 controls the probe to touch the VCC point and the GND point of the electronic component according to the touch stress. In the embodiment, the touch stress can be detected by a pressure sensor of the probe when the probe touches the VCC point and the GND point of the electronic component.

In block 312, the method 300 obtains a positive voltage signal output from the VCC point when the probe touches the VCC point, and obtains a negative voltage signal outputted from the GND point when the probe touches the GND point. In block 312, the method 300 further measures the signal integrity of the positive voltage signal and the negative voltage signal. The measurement can be performed using the oscilloscope.

In block 314, the method 300 determines whether the intended electronic components of the electronic product have been tested by checking if all the test labels of the intended electronic components have been scanned. If all of the intended electronic components of the electronic product have been tested, block 316 is implemented. Otherwise, if any electronic component of the electronic product needs to be tested, the method 300 returns to block 304.

In block 316, the method 300 generates a signal integrity report of the electronic product based on measured results of the tested electronic components. The signal integrity report can be stored in the storage device or displayed on the display device for the designer to evaluate the performance of the electronic product.

All of the processes described above may be embodied in, and fully automated via, functional code modules executed by one or more general purpose processors of computing devices. The code modules may be stored in any type of non-transitory readable medium or other storage device. Some or all of the methods may alternatively be embodied in specialized hardware. Depending on the embodiment, the non-transitory readable medium may be a hard disk drive, a compact disc, a digital video disc, a tape drive or other suitable storage medium.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size and arrangement of parts within the principles of the present disclosure, up to and including the full extent established by the broad general meaning of the terms used in the claims.

What is claimed is:

1. A signal integrity test apparatus comprising:
a robot device comprising a first robot arm and a second robot arm;
a host computer being connected to an electronic product comprising a plurality of electronic components, the host computer comprising:
at least one processor, and
a storage device storing a computer-readable program comprising instructions that, when executed by the at least one processor, causes the at least one processor to:
control the first robot arm to move a camera device to an electronic component to be tested of the electronic product, and control the camera device to capture an image of a test label coupled to the electronic component;
identify a VCC point and a GND point of the electronic component from the image of the test label, and determine an insertion direction of the probe and a touch stress when the probe touches the electronic component;
control the second robot arm to move a probe to the electronic component according to the insertion direction of the probe;
control the probe to touch the VCC point and the GND point of the electronic component according to the touch stress;
obtain a positive voltage signal from the VCC point when the probe touches the VCC point, and obtain a negative voltage signal from the GND point when the probe touches the GND point;
control an oscilloscope to measure signal integrity of the positive voltage signal and the negative voltage signal; and
generate a signal integrity report of the electronic product based on the measured results of all electronic components of the electronic product.

2. The apparatus according to claim 1, wherein the camera device is fixed on the first robot arm, and the probe is fixed on the second robot arm.

3. The apparatus according to claim 1, wherein each of the electronic components comprises a test label that identifies a location of the electronic component and a name of a signal outputted from the electronic component.

4. The apparatus according to claim 3, wherein the test label comprises a center hole, a signal identification code, and an insertion direction of the probe when the probe enters into the center hole of the test label to test the electronic component.

5. The apparatus according to claim 4, wherein the signal identification code stores a plurality of parameters that comprise the name of the signal outputted from the electronic component, and the touch stress when the probe touches the electronic component.

6. The apparatus according to claim 4, wherein the signal identification code is a bar code or a quick response (QR) code.

7. A method for automatically testing signal integrity of an electronic product, the method comprising:
controlling a first robot arm of a robot device to move a camera device to an electronic component to be tested of the electronic product, and controlling the camera device to capture an image of a test label coupled to the electronic component;
identifying a VCC point and a GND point of the electronic component from the image of the test label, and determining an insertion direction of the probe and a touch stress when the probe touches the electronic component;
controlling a second robot arm of the robot device to move a probe to the electronic component according to the insertion direction of the probe;
controlling the probe to touch the VCC point and the GND point of the electronic component according to the touch stress;
obtaining a positive voltage signal from the VCC point when the probe touches the VCC point, and obtaining a negative voltage signal from the GND point when the probe touches the GND point;
controlling an oscilloscope to measure signal integrity of the positive voltage signal and the negative voltage signal; and
generating a signal integrity report of the electronic product based on the measured results of all electronic components of the electronic product.

8. The method according to claim 7, wherein the camera device is fixed on the first robot arm, and the probe is fixed on the second robot arm.

9. The method according to claim 7, wherein each of the electronic components comprises a test label that identifies a location of the electronic component and a name of a signal outputted from the electronic component.

10. The method according to claim 9, wherein the test label comprises a center hole, a signal identification code, and an insertion direction of the probe when the probe enters into the center hole of the test label to test the electronic component.

11. The method according to claim 10, wherein the signal identification code stores a plurality of parameters that comprise the name of the signal outputted from the electronic component, and the touch stress when the probe touches the electronic component.

12. The method according to claim 10, wherein the signal identification code is a bar code or a quick response (QR) code.

13. A non-transitory storage medium having stored thereon instructions that, when executed by at least one processor of a computing device, causes the least one processor to execute instructions of a method for automatically testing signal integrity of an electronic product, the method comprising:
controlling a first robot arm of a robot device to move a camera device to an electronic component to be tested of the electronic product, and controlling the camera device to capture an image of a test label coupled to the electronic component;
identifying a VCC point and a GND point of the electronic component from the image of the test label, and determining an insertion direction of the probe and a touch stress when the probe touches the electronic component;
controlling a second robot arm of the robot device to move a probe to the electronic component according to the insertion direction of the probe;
controlling the probe to touch the VCC point and the GND point of the electronic component according to the touch stress;
obtaining a positive voltage signal from the VCC point when the probe touches the VCC point, and obtaining a negative voltage signal from the GND point when the probe touches the GND point;
controlling an oscilloscope to measure signal integrity of the positive voltage signal and the negative voltage signal; and
generating a signal integrity report of the electronic product based on the measured results of all electronic components of the electronic product.

14. The storage medium according to claim 13, wherein the camera device is fixed on the first robot arm, and the probe is fixed on the second robot arm.

15. The storage medium according to claim 13, wherein each of the electronic components comprises a test label that identifies a location of the electronic component and a name of a signal outputted from the electronic component.

16. The storage medium according to claim 15, wherein the test label comprises a center hole, a signal identification code, and an insertion direction of the probe when the probe enters into the center hole of the test label to test the electronic component.

17. The storage medium according to claim 16, wherein the signal identification code stores a plurality of parameters that comprise the name of the signal outputted from the electronic component, and the touch stress when the probe touches the electronic component.

18. The storage medium according to claim 16, wherein the signal identification code is a bar code or a quick response (QR) code.
